(19) United States
(12) Patent Application Publication
(10) Pub. No.: US 2019/0232333 A1
(43) Pub. Date: Aug. 1, 2019

(54) METHOD FOR PRODUCING POLYIMIDE LAMINATE AND METHOD FOR PRODUCING FLEXIBLE CIRCUIT BOARD

(71) Applicant: UBE INDUSTRIES, LTD., Yamaguchi (JP)

(72) Inventors: Kazutaka NARITA, Yamaguchi (JP); Takeshige NAKAYAMA, Yamaguchi (JP); Naoki KITAYAMA, Yamaguchi (JP); Shohei INOUE, Yamaguchi (JP)

(21) Appl. No.: 16/311,432

(22) PCT Filed: Jul. 14, 2017
(86) PCT No.: PCT/JP2017/025645

§ 371 Date: Dec. 19, 2018

(30) Foreign Application Priority Data
Jul. 15, 2016 (JP) 2016-140571

(51) Int. Cl. B05D 3/02; B32B 27/34; C08J 5/18; H05K 1/03

(52) U.S. Cl. CPC B05D 3/0227; B32B 27/34; H05K 1/0393; H05K 1/0306; C08J 5/18

(57) ABSTRACT

Disclosed is a method for producing a polyimide laminate, the method including the steps of applying a polyimide precursor solution onto a substrate and heating the polyimide precursor solution, to thereby form a polyimide film layer on the substrate. The substrate is any plate selected from a glass plate, a metal plate, and a ceramic plate. The heating step includes irradiation with far infrared rays using an infrared heater that generates a maximum radiant energy at an infrared wavelength of 3.5 to 6 μm. The highest heating temperature is preferably 350 to 550° C. The time required to increase the temperature from 180 to 280° C. during a temperature-increasing process is preferably 2 minutes or longer.

### TECHNICAL FIELD

The present invention relates to a method for producing a polyimide laminate comprising a substrate and a polyimide film layer formed thereon. Also, the present invention relates to a method for producing a flexible circuit board.

### BACKGROUND ART

Polyimides, which are obtained by reacting a tetracarboxylic acid compound with a diamine, have excellent in various properties such as heat resistance, mechanical strength, electrical properties, and solvent resistance, and films made of polyimides are widely used as insulating substrates for electronic circuit boards. A polyimide film is produced by applying a polyimide precursor such as polyamic acid (polyamide acid) to a substrate to form a film, and imidizing the polyimide precursor in the film through heating. For heating, a method using hot air is widely used, but a method using infrared irradiation has also been proposed in order to eliminate temperature irregularity or to reduce the heating time.

For example, Patent Literature 1 discloses a method for uniformly heating a film by using a heating furnace for continuously subjecting a film to heat treatment in which a plurality of radiation heat sources are installed, and individually adjusting the temperature settings of the radiation heat sources. Specifically, a plurality of far infrared heaters are arranged in a film width direction, and the temperature of each far infrared heater is adjusted to be within a range of 700 to 750° C., to thereby obtain a uniform film.

Patent Literature 2 discloses a method in which heating is performed using near infrared irradiation. In particular, Patent Literature 2 disclose that near infrared rays with a wavelength of 2.5 to 3.5 μm can give energy selectively to reactive groups (imino group, hydroxy group, etc.) that participate in an imidization reaction to thereby improve the rate of the imidization reaction.

### CITATION LIST

### Patent Literature

Patent Literature 1: JP H11-245244A

Patent Literature 2: WO 2014/057731

### SUMMARY OF INVENTION

It is an object of the present invention to provide a method for producing a polyimide laminate which can form a polyimide film layer on a substrate in a short period of time, and more particularly to provide a method which can form a polyimide film layer in a short period of time with no occurrence of foaming in a heat treatment.

The present invention relate to the following items.
1. A method for producing a polyimide laminate, the method including the steps of:

applying a polyimide precursor solution onto a substrate and performing heat treatment thereon, to thereby form a polyimide film layer on the substrate,

wherein the substrate is any plate selected from a glass plate, a metal plate, and a ceramic plate, and

the step of performing heat treatment includes the substep of heating by irradiation with far infrared rays using an infrared heater that generates a maximum radiant energy at an infrared wavelength of 3.5 to 6 μm.
2. The method for producing a polyimide laminate as set forth in the item 1 above,

wherein the substep of heating involves a temperature-increasing process from room temperature to a highest heating temperature,

the highest heating temperature is 350 to 550° C.,

the time required to increase the temperature from 180 to 280° C. during the temperature-increasing process is 2 minutes or longer, and

the time required for the substep of heating is within 3 hours.
3. The method for producing a polyimide laminate as set forth in the item 1 or 2 above,

wherein the polyimide precursor solution contains a polyamic acid constituted by a repeating unit represented by chemical formula (1) below:

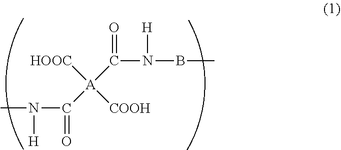

wherein A is at least one group selected from tetravalent groups represented by chemical formulae (2) and (3) below, and B is at least one group selected from divalent groups represented by chemical formulae (4) and (5) below:

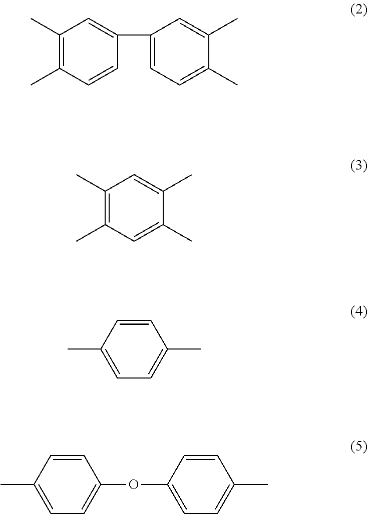

4. A method for producing a flexible circuit board, the method including the steps of:

producing a polyimide laminate according to the method as set forth in any one of the items 1 to 3 above;

forming an electronic circuit on the polyimide film layer of the polyimide laminate; and

removing the polyimide film layer with the electronic circuit formed thereon from the substrate.

### ADVANTAGEOUS EFFECTS OF INVENTION

According to the present invention, a polyimide film layer can be formed on a substrate in a short period of time with no occurrence of foaming during heat treatment. Moreover, light-transmitting properties and heat resistance of the polyimide film layer to be obtained can be improved.

### DESCRIPTION OF EMBODIMENTS

A method for producing a polyimide laminate according to the present invention includes the steps of applying a polyimide precursor solution containing a polyamic acid obtained, for example, from a tetracarboxylic acid component, such as pyromellitic dianhydride or 3,3′,4,4′-biphenyltetracarboxylic dianhydride, and a diamine component, such as 4,4′-diaminodiphenyl ether or paraphenylenediamine, onto the substrate to form a polyimide precursor film layer, and performing heat treatment including the substep of heating by infrared irradiation using an infrared heater that generates the maximum radiant energy at an infrared wavelength within a specific range, to thereby form a polyimide film layer on the substrate.

The polyamic acid used in the present invention can be suitably obtained, as a polyamic acid solution in which the polyamic acid is uniformly dissolved in a solvent, by reacting a tetracarboxylic acid component such as tetracarboxylic dianhydride and a diamine component in substantially equimolar amounts in the solvent by agitating and mixing the components at a relatively low temperature that can suppress an imidization reaction. The molecular weight of the polyamic acid used in the present invention is not limited; however, the molecular weight of a polyamic acid to be obtained can be adjusted by the molar ratio between the tetracarboxylic acid component and the diamine component to be reacted with each other. The molar ratio between the tetracarboxylic acid component and the diamine component (tetracarboxylic acid component/diamine component) is usually about 0.90 to 1.10.

Also, normally, but not exclusively, the reaction temperature is 25° C. to 100° C., preferably 40° C. to 80° C., and more preferably 50° C. to 80° C., and the reaction time is about 0.1 to 24 hours and preferably about 2 to 12 hours. A solution containing the polyamic acid can be efficiently obtained by setting a reaction temperature and a reaction time within the above-described ranges. The reaction is usually performed in an inert gas atmosphere and preferably in a nitrogen gas atmosphere, although it can also be performed in an air atmosphere.

The solvent that can be used above is not limited as long as the polyamic acid can be dissolved therein, and preferred examples thereof include N,N-di-lower-alkyl carboxylamides, such as N,N-dimethylformamide, N,N-dimethylacetamide, N,N-diethylacetamide, and N,N-dimethylmethoxyacetamide, N-methyl-2-pyrrolidone, N-ethyl-2-pyrrolidone, dimethyl sulfoxide, dimethyl sulfone, 1,3 -dimethyl-2-imidazolidinone, γ-butyrolactone, diglyme, m-cresol, hexamethylphosphoramide, N-acetyl-2-pyrrolidone, hexamethylphosphoramide, ethyl cellosolve acetate, diethylene glycol dimethyl ether, sulfolane, and p-chlorophenol. The solvent may also be a mixture of two or more solvents.

The tetracarboxylic acid component and the diamine component that can be used in the present invention are not limited. However, with regard to the tetracarboxylic acid component, it is preferable to use pyromellitic dianhydride and 3,3′,4,4′-biphenyltetracarboxylic dianhydride or either of them as the main component. More specifically, it is preferable that pyromellitic dianhydride and 3,3′,4,4′-biphenyltetracarboxylic dianhydride or either of them account for 50 mol % or greater, preferably 80 mol % or greater, more preferably 90 mol % or greater, and even more preferably 100 mol % of the tetracarboxylic acid component.

With regard to the diamine component, it is preferable to use 4,4′-diaminodiphenyl ether and paraphenylenediamine or either of them as the main component. More specifically, it is preferable that 4,4′-diaminodiphenyl ether and paraphenylenediamine or either of them account for 50 mol % or greater, preferably 80 mol % or greater, more preferably 90 mol % or greater, and even more preferably 100 mol % of the diamine component.

Preferably, the polyimide precursor solution used in the present invention contains a polyamic acid constituted by a repeating unit represented by chemical formula (1) below, and the repeating unit represented by chemical formula (1) is particularly preferably obtained from 3,3′,4,4′-biphenyltetracarboxylic dianhydride and paraphenylenediamine.

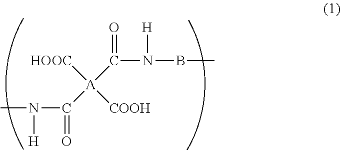

In the chemical formula (1), A is preferably at least one group selected from tetravalent groups represented by chemical formulae (2) and (3) below, and B is preferably at least one group selected from divalent groups represented by chemical formulae (4) and (5) below:

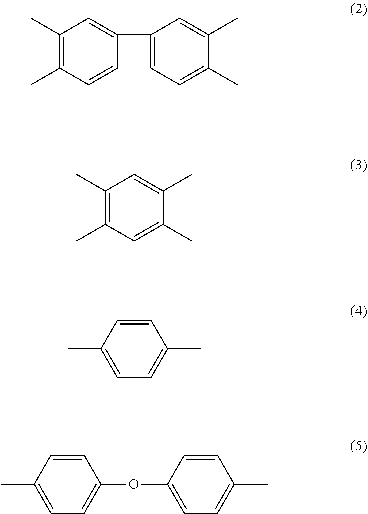

The polyamic acid solution thus obtained can be used as the polyimide precursor solution as-is. Alternatively, any of desired component may be added thereto, if necessary, and then the resultant solution can be used.

In the present invention, the solid content of the polyamic acid (in terms of polyimide) in the polyimide precursor solution is not limited, but is 2 to 50 mass% and preferably 5 to 40 mass%. The solution viscosity (rotational viscosity) of the polyimide precursor solution at 30° C. is not limited, but is 1 to 3000 poise and preferably 5 to 2000 poise.

The polyimide precursor solution used in the present invention may also contain a dehydrating agent and an imidization catalyst. Examples of the dehydrating agent include acetic anhydride. Examples of the imidization catalyst include imidazole compounds, such as 1,2-dimethylimidazole, heterocyclic compounds containing nitrogen atoms, such as isoquinoline, and basic compounds, such as triethylamine and triethanolamine.

In the present invention, it is preferable to carry out the steps of applying the above-described polyimide precursor solution onto a substrate to form a polyimide precursor film layer, and then performing heat treatment including the substep of heating the polyimide precursor film layer by irradiating it with far infrared rays using an infrared heater that generates the maximum radiant energy at an infrared wavelength (peak wavelength) in the far infrared region, to thereby form a polyimide film layer on the substrate. Infrared rays from an infrared heater have a wavelength distribution, and. in the present invention, an infrared heater having a peak infrared wavelength in the far infrared region is used. Thus, in the present invention, heat can be directly and uniformly applied to an object to be heated, without conveyance by a medium such as air or nitrogen, and the heating time taken to complete the imidization can be reduced compared with heating using only hot air. Thus, heat deterioration of the polyimide resin can be minimized, and the obtained polyimide film layer has improved light-transmitting properties and heat resistance. In the substep of heating by irradiation with far infrared rays, heating using hot air may additionally be performed at the same time. The time required to perform the heat treatment from the start of irradiation with far infrared rays to the completion of cooling is preferably within 4 hours, more preferably within 2 hours, and even more preferably within 1 hour.

The substrate is not limited as long as the polyimide film layer can be formed on the surface thereof, but is desirably made of a material that is capable of withstanding the heat treatment and has a low thermal expansion coefficient. The shape of the substrate is not limited, but is usually a planar shape. Specifically, any plate selected from, for example, metal plates made of various kinds of metals, ceramic plates made of various kinds of ceramics, and glass plates can be used as the substrate. In particular, glass plates can be suitably used in view of their high-temperature resistance and linear expansion coefficients. The method for applying the polyimide precursor solution onto the substrate is not limited as long as a coating with a small thickness can be formed, and conventionally known methods such as spin coating, screen printing, bar coating, and electrodeposition, for example, can be suitably used.

In the present invention, the substrate is formed of a material that substantially does not transmit gas, such as a glass plate. For this reason, during the heat treatment, volatile components (solvent, water resulting from the imidization, etc.) are not allowed to evaporate from a surface of the polyimide precursor film layer that faces the substrate, but only evaporate from the other surface, that is, the surface that faces air (or another gas). In the production method according to the present invention, the polyimide precursor film layer is not heat-treated in a state in which it is separated from the substrate, but rather is heated in a state in which the volatile components are allowed to evaporate from only one surface, until the imidization is completed.

In the present invention, “far infrared rays” refers to infrared rays that have a wavelength of 4 μm or greater, and the peak wavelength in the far infrared region means that the peak wavelength is 4 μm or greater. The peak wavelength of infrared rays radiating from an infrared heater can be estimated from the heater temperature. The so-called “Wien's displacement law” states that the wavelength at which the radiant energy from a blackbody peaks is inversely proportional to the temperature, and the peak wavelength can be estimated using this law. For example, the wavelength at which the radiant energy peaks is estimated about 4 μm when the heater temperature is 450° C., about 5 μm when the heater temperature is 300° C., and 3 μm when the heater temperature is 700° C. In the present invention, it is preferable that the peak wavelength be 4 μm or greater. In other words, it is preferable to use an infrared heater whose temperature is set to be lower than about 450° C.

The shorter the peak wavelength of infrared rays used for irradiation, the larger the total amount of radiant energy. However, infrared rays having a wavelength of around 3 μm are efficiently absorbed by water, and thus when using such infrared rays, foaming in the polyimide precursor film layer during the heat treatment is likely to occur, making it difficult to form a uniform polyimide film layer. For this reason, in the present invention, it is preferable that the peak wavelength be 3.5 μm or greater. On the other hand, as the peak wavelength is longer, the total amount of radiant energy becomes more insufficient, and therefore it is more difficult to perform sufficient heat treatment for completing the imidization reaction. For this reason, in the present invention, it is preferable that the peak wavelength is 6 μm or less.

It is preferable that the substep of heating through irradiation with far infrared rays involve a gradual temperature-increasing process from room temperature (25° C.) to the highest heating temperature. The highest heating temperature is preferably 350 to 550° C. and more preferably 400 to 500° C. If the highest heating temperature is excessively low, the imidization reaction may not be completed, and therefore a polyimide film layer with sufficient heat resistance and mechanical properties may not be obtained. Also, if the highest heating temperature is excessively high, the polyimide film layer may be deteriorated by heat. The time required for the substep of heating is preferably within 3 hours, more preferably within 2 hours, and even more preferably within 1 hour from the start of the irradiation with far infrared rays. The time required for the substep of heating refers to the time from the start of the temperature increase until the start of the substep of cooling, and includes a time period for which the highest heating temperature is kept. If the time required for the substep of heating is excessively long, improvement in the light-transmitting properties and the heat resistance of the polyimide film layer to be obtained can no longer be expected. Also, if the temperature is increased at an excessively high rate, the volatile components rapidly vaporize, making it more likely that foaming will occur in the polyimide precursor film layer.

In view of suppressing foaming, it is preferable that, during the temperature-increasing process, the time required to increase the temperature from 180° C. to 280° C. be 2 minutes or longer. Also, in view of reducing the heat treatment time, the time required to increase the temperature from 180° C. to 280° C. is preferably 90 minutes or shorter, more preferably 60 minutes or shorter, and even more preferably 45 minutes or shorter. During the temperature-increasing process, the temperature range from 180° C. to 280° C. may affects production of the polyimide film in terms of foaming that may occur while the temperature is increasing, and setting the time required for this temperature range within the above-described range can advantageously reduce the temperature-increasing time while suppressing foaming.

The time required for the heating substep and the time required to increase the temperature from 180° C. to 280° C. can be adjusted as appropriate by, for example, using a ceramic heater or a quartz heater as a heating element of the infrared heater, or adjusting the energy output of the infrared heater. Also, heating from the start of the irradiation with far infrared rays to reaching the highest heating temperature may be performed at a constant temperature-increasing rate, or at varied temperature-increasing rates. A certain temperature may also be kept for a predetermined period of time in the middle of the temperature-increasing process. After the highest heating temperature is reached, the highest heating temperature can be kept for a predetermined period of time.

The thickness of the polyimide film layer formed on the substrate is not limited, but is less than 50 μm, preferably 30 μm or less, and more preferably 20 μm or less. As, the thickness is larger beyond the above-described range, it is more likely that an excessive amount of volatile components (outgas) will be generated, and that foaming will occur in the heat treatment.

A flexible circuit board can be obtained by forming an electronic circuit on a polyimide film layer that is obtained according to the present invention and removing the polyimide film layer with the electronic circuit formed thereon from the substrate. This flexible circuit board can be suitably used in applications such as liquid crystal displays, EL displays, electronic paper, and thin-film solar cells.

### EXAMPLES

The present invention will be even more specifically described by way of examples, but the present invention is not limited to these examples.

Methods for determining the characteristics used in the examples below are as follows:

### Measurement of 1% Weight Loss Temperature: TGA Measurement Method

A polyimide film layer was removed from a substrate, and characterized by TG-DTA using a TG-DTA 2000S (MAC Science). Specifically, the temperature was increased from room temperature (25° C.) to 700° C. at a rate of 20° C./min, and the 1% weight loss temperature was measured taking the weight at 150° C. as 100%. The measurement was performed in a nitrogen atmosphere.

### Light Transmittance

The light transmittance of a polyimide film layer at 450 nm was determined using a spectrophotometer U-2910 (manufactured by Hitachi High-Technologies Corporation). In the case where the thickness of a polyimide film layer was not 10 μm, the light transmittance obtained was converted, using the Lambert-Beer law, into the light transmittance of a film with a thickness of 10 μm, which was taken as the light transmittance of the polyimide film layer.

### Example 1

U-Varnish S (a polyimide precursor solution) manufactured by Ube Industries, Ltd. was applied onto a glass substrate using a spin coater so as to obtain a polyimide layer with a thickness of 10 μm. The resultant was heated on a hot plate at 80° C. for 10 minutes, and then put in a far infrared heating furnace (the wavelength of the maximum radiant energy: 4 to 5 μm). The temperature in the furnace was gradually increased from room temperature (25° C.) to 450° C., followed by cooling to 100° C., and thus, a polyimide laminate was obtained. The heat treatment time (time from the start of the temperature increase to the end of the cooling) was 1 hour. With regard to the obtained polyimide film layer, no foaming or the like was observed in the appearance thereof, the film thickness was 10 μm, the 1% weight loss temperature was 582° C., and the transmittance at 450 nm was 64%.

### Example 2

A polyimide laminate was obtained in the same manner as in Example 1 except that the heat treatment time was 2 hours. With regard to the obtained polyimide film layer, no foaming or the like was observed in the appearance thereof, the film thickness was 10 μm, the 1% weight loss temperature was 581° C., and the transmittance at 450 nm was 63%.

### Example 3

A polyimide laminate was obtained in the same manner as in Example 2 except that an adjustment was made so as to obtain a polyimide layer with a thickness of the 20 p.m. With regard to the obtained polyimide film layer, no foaming or the like was observed in the appearance thereof, the film thickness was 20 μm, the 1% weight loss temperature was 580° C., and the transmittance at 450 nm was 63% (value calculated in terms of the thickness of 10 μm).

### Comparative Example 1

A polyimide laminate was obtained in the same manner as in Example 1 except that the heat treatment was performed using a near infrared heating furnace (the wavelength of the maximum radiant energy: 2.5 to 3.5 μm). Foaming was observed over the entire surface of the obtained polyimide film layer.

### Comparative Example 2

A polyimide laminate was obtained in the same manner as in Example 3 except that the heat treatment was performed using a near infrared heating furnace. Foaming was observed over the entire surface of the obtained polyimide film layer.

### Example 4

U-Varnish S (a polyimide precursor solution) manufactured by Ube Industries, Ltd. was applied onto a glass substrate using a spin coater so as to obtain a polyimide layer with a thickness of 10 μm. The resultant was heated on a hot plate at 80° C. for 10 minutes. After that, heat treatment was performed under the conditions shown in Table 1 using a far infrared heating furnace (the wavelength of the maximum radiant energy: 4 to 5 μm) to obtain a polyimide laminate. The temperature was increased from room temperature (25° C.). The time required to increase the temperature from 180° C. to 280° C. during the temperature-increasing process was 2 minutes, and the time required for the heating substep (time from the start of the temperature increase to the start of cooling) was 13.5 minutes. No foaming or the like was observed in the appearance of the obtained polyimide film layer. Table 1 shows the results.

### Example 5

A polyimide laminate was obtained in the same manner as in Example 4, by performing the heat treatment under the conditions shown in Table 1. The time required to increase the temperature from 180° C. to 280° C. during the temperature-increasing process was 5 minutes, and the time required for the heating substep was 26.25 minutes. No foaming or the like was observed in the appearance of the obtained polyimide film layer. Table 1 shows the results.

### Example 6

A polyimide laminate was obtained in the same manner as in Example 4, by performing the heat treatment under the conditions shown in Table 1. The time required to increase the temperature from 180° C. to 280° C. during the temperature-increasing process was 90 minutes, and the time required for the heating substep was 94.25 minutes. No foaming or the like was observed in the appearance of the obtained polyimide film layer. Table 1 shows the results.

### Example 7

A polyimide laminate was obtained in the same manner as in Example 4, by performing the heat treatment under the conditions shown in Table 1. The time required to increase the temperature from 180° C. to 280° C. during the temperature-increasing process was 32 minutes, and the time required for the heating substep was 73.5 minutes. No foaming or the like was observed in the appearance of the obtained polyimide film layer. Table 1 shows the results.

### Example 8

A polyimide laminate was obtained in the same manner as in Example 7 except that adjustments were made so as to obtain a polyimide layer with a film thickness of 20 pm. No foaming or the like was observed in the appearance of the obtained polyimide film layer. Table 1 shows the results.

### Example 9

A polyimide laminate was obtained in the same manner as in Example 4, by performing the heat treatment under the conditions shown in Table 1. The time required to increase the temperature from 180° C. to 280° C. during the temperature-increasing process was 80 minutes, and the time required for the heating substep was 170 minutes. No foaming or the like was observed in the appearance of the obtained polyimide film layer. Table 1 shows the results.

### Comparative Example 3

A polyimide laminate was obtained in the same manner as in Example 1, by performing the heat treatment under the conditions shown in Table 1, except that the heat treatment was performed using a near infrared heating furnace (the wavelength of the maximum radiant energy: 2.5 to 3.5 μm). Foaming was observed over the entire surface of the obtained polyimide film layer.

### Comparative Example 4

A polyimide laminate was obtained under the same conditions as in Comparative Example 3 except that adjustments were made so as to obtain a polyimide layer with a thickness of 20 μm. Foaming was observed over the entire surface of the obtained polyimide film layer.

### Reference Example

A polyimide laminate was obtained in the same manner as in Example 9 except that a heating furnace of a hot air circulation type was used. With regard to the obtained polyimide film layer, no foaming or the like was observed in the appearance thereof, the film thickness was 10 μm, the 1% weight loss temperature was 570° C., and the transmittance at 450 nm was 54%.

TABLE 1

| | Ex. 4 | Ex. 5 | Ex. 6 | Ex. 7 | Ex. 8 | Ex. 9 | Com. Ex. 3 | Com. Ex. 4 | Ref. Ex. |
|---|---|---|---|---|---|---|---|---|---|
| Heating method | Far | Far | Far | Far | Far | Far | Near | Near | Hot air |
| | infrared | infrared | infrared | infrared | infrared | infrared | infrared | infrared | circulation |
| | rays | rays | rays | rays | rays | rays | rays | rays | |
| 180° C. → 280° C. | 2 | 5 | 90 | 32 | 32 | 80 | 2 | 2 | 80 |
| Required time (min) | | | | | | | | | |
| Highest heating | 450 | 450 | 450 | 450 | 450 | 450 | 450 | 450 | 450 |
| temperature (° C.) | | | | | | | | | |
| Time required for | 13.5 | 26.25 | 94.25 | 73.5 | 73.5 | 170 | 13.5 | 13.5 | 170 |
| heating step (min) | | | | | | | | | |
| Film thickness (μm) | 10 | 10 | 10 | 10 | 20 | 10 | 10 | 20 | 10 |
| State of film | No | No | No | No | No | No | Foaming over | Foaming over | No |
| | foaming | foaming | foaming | foaming | foaming | foaming | the entire | the entire | foaming |
| | | | | | | | surface | surface | |
| 1% Weight loss | 585 | 587 | 585 | 588 | 583 | 582 | 558 | 553 | 570 |
| temperature (° C.) | | | | | | | | | |
| Transmittance at 450 | 67 | 67 | 71 | 68 | 65 | 65 | 58 | 57 | 54 |
| nm (%)* | | | | | | | | | |

*For films with film thickness of 20 μm, numerical values calculated in terms of film thickness of 10 μm are shown.
Maximum radiant energy wavelength of far infrared rays: 4 to 5 μm
Maximum radiant energy wavelength of near infrared rays: 2.5 to 3.5 μm

As is clear from the results shown in Table 1, it was found that, according to the methods of the respective examples, a polyimide film layer can be formed in a short period of time with no occurrence of foaming. Moreover, it was found that polyimide films obtained according to the methods of the respective examples have superior light-transmitting properties and heat resistance to those of polyimide films obtained according to the methods of the comparative examples. In particular, as is clear from the comparison between Example 9 and the reference example, even under the same heating parameters, a polyimide film with superior light-transmitting properties and heat resistance is obtained in the case where heating is performed through irradiation with far infrared rays, as compared with the case where heating is performed using hot air.

1. A method for producing a polyimide laminate, the method comprising the steps of:
applying a polyimide precursor solution onto a substrate and performing heat treatment thereon, to thereby form a polyimide film layer on the substrate,
wherein the substrate is any plate selected from a glass plate, a metal plate, and a ceramic plate, and the step of performing heat treatment comprises the substep of heating by irradiation with far infrared rays using an infrared heater that generates a maximum radiant energy at an infrared wavelength of 3.5 to 6 μm.

2. The method for producing a polyimide laminate according to claim 1,
wherein the substep of heating involves a temperature-increasing process from room temperature to a highest heating temperature,
the highest heating temperature is 350 to 550° C., the time required to increase the temperature from 180 to 280° C. during the temperature-increasing process is 2 minutes or longer, andthe time required for the substep of heating is within 3 hours.

3. The method for producing a polyimide laminate according to claim 1 r 2,
wherein the polyimide precursor solution contains a polyamic acid constituted by a repeating unit represented by chemical formula (1) below: 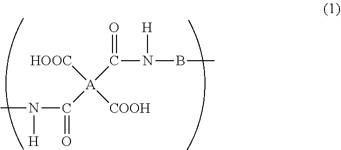
wherein A is at least one group selected from tetravalent groups represented by chemical formulae (2) and (3) below, and B is at least one group selected from divalent groups represented by chemical formulae (4) and (5) below:

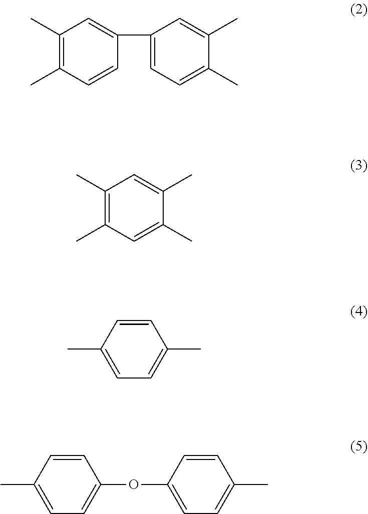

4. A method for producing a flexible circuit board, the method comprising the steps of:
producing a polyimide laminate by the method according to claim 1; forming an electronic circuit on the polyimide film layer of the polyimide laminate;
and removing the polyimide film layer with the electronic circuit formed thereon from the substrate.

5. The method for producing a polyimide laminate according to claim 2,
wherein the polyimide precursor solution contains a polyamic acid constituted by a repeating unit represented by chemical formula (1) below: 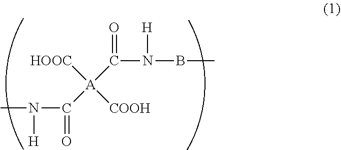
wherein A is at least one group selected from tetravalent groups represented by chemical formulae (2) and (3) below, and B is at least one group selected from divalent groups represented by chemical formulae (4) and (5) below:

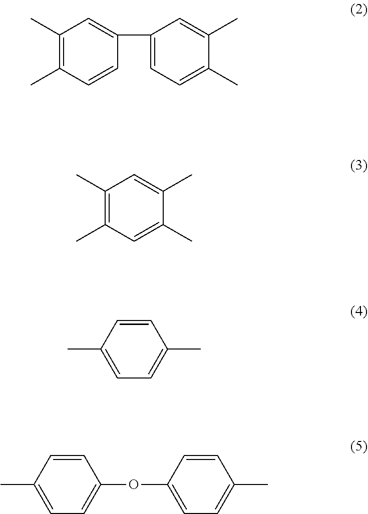

6. A method for producing a flexible circuit board, the method comprising the steps of:
producing a polyimide laminate by the method according to claim 2; forming an electronic circuit on the polyimide film layer of the polyimide laminate; and removing the polyimide film layer with the electronic circuit formed thereon from the substrate.

7. A method for producing a flexible circuit board, the method comprising the steps of:
producing a polyimide laminate by the method according to claim 3; forming an electronic circuit on the polyimide film layer of the polyimide laminate; and
removing the polyimide film layer with the electronic circuit formed thereon from the substrate.

8. A method for producing a flexible circuit board, the method comprising the steps of:
producing a polyimide laminate by the method according to claim 5; forming an electronic circuit on the polyimide film layer of the polyimide laminate; and
removing the polyimide film layer with the electronic circuit formed thereon from the substrate.
